(19) United States
(12) Patent Application Publication
(10) Pub. No.: US 2010/0091477 A1
(43) Pub. Date: Apr. 15, 2010

(54) PACKAGE, AND FABRICATION METHOD FOR THE PACKAGE

(75) Inventors: Kazutaka TAKAGI, Kawasaki-shi (JP); Tsuyoshi Hasegawa, Kawasaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/579,023

(22) Filed: Oct. 14, 2009

(30) Foreign Application Priority Data
Oct. 14, 2008 (JP) 2008-265400
Feb. 13, 2009 (JP) 2009-031677

(51) Int. Cl. H05K 7/00; H01L 21/00

(52) U.S. Cl. 361/820; 438/106; 257/E21.001

(57) ABSTRACT

A package includes a conductive base plate; a ceramic wall configured to house a semiconductor device and a circuit board disposed adjoining of the semiconductor device, the ceramic wall configured to be disposed on the conductive base plate, the ceramic wall configured to include a frame shape having a screw hole in four corners; a metal seal ring configured to include a framed shape and be disposed on the ceramic wall; and a ceramic cap configured to be disposed on the metal seal ring, and the ceramic wall is screwed to the conductive base plate through the screw hole, and the package can radiate heat satisfactory in the heat generation from the semiconductor device, and can improve reliability, and can be applied to the high frequency of the microwave/millimeter wave/sub-millimeter wave band.

### CROSS REFERENCE TO RELATED APPLICATIONS AND INCORPORATION BY REFERENCE

This application is based upon and claims the benefit of priority from prior Japanese Patent Applications No. P2008-265400 filed on Oct. 14, 2008 and No. P2009-31677 filed on Feb. 13, 2009, the entire contents of which are incorporated herein by reference.

### TECHNICAL FIELD

The present invention relates to a package and a fabrication method for the package. More specifically, in a package for mounting heating elements, such as a semiconductor device composing various kinds of electronic parts, the present invention relates to a package which can radiate heat satisfactory in the heat generation from a heating element, and a fabrication method for the same.

### BACKGROUND ART

Conventionally, a package is required that the heat radiated by a semiconductor device housed should be made to radiate efficiently, and the semiconductor device should be operated to stability over a long period of time.

Accordingly, the conventional package has achieved heat dissipation by screwing a metal base substance in which a semiconductor device is mounted on the surface of a heat sink (for example, refer to Patent Literature 1).

Generally, as for a semiconductor device, a semiconductor element composing electronic parts which are heating elements is housed and disposed in a package which is a heating element mounted part, and a connecting terminal for external connection is provided in an extended condition on the peripheral wall of the package. Then, the semiconductor device is used by electrically connecting the connecting terminal for connection to an external circuit. Since the semiconductor device will cause its performance degradation by the above-mentioned use if the semiconductor element occurs the heat and then the temperature rises, a method of exhausting the occurred heat to external and maintaining the temperature at an acceptable value is adopted.

In such a semiconductor device, the package structure achieving the heat radiation to a radiator is adopted by providing a through-hole in the four corners around a mounting part in which the semiconductor element in a package base is housed, and screwing and fixing to the heat sink using the through-hole.

However, since the above-mentioned package structure has a configuration for contacting by pressuring and being fixed the four corners of the mounting part in the package base to the heat sink, it has a problem that it is difficult to contact the whole mounting side surface of the mounting part with uniform contact thermal resistance by pressure, and is difficult to obtain sufficient heat transferring efficiency. Although it is possible to achieve uniformity of the contact thermal resistance by increasing the fabricating accuracy for the flatness of the package base, it has a problem that the processing fabrication becomes very difficult.

Then, a package structure composed so that a highly efficient heat transfer might be achieved is proposed for such the package structure, without being affected to the fabricating accuracy of the package base by influence, by mounting a screw clamp unit of a package base on a heat sink via a graphite sheet which is excellent in thermal conduction efficiency, and performing pressure fixation of the package base at the radiator using a through-hole provided in the package base's four corners (for example, refer to Patent Literature 1).

Moreover, there is also a thing of a configuration of applying grease for heat radiation between the package base and the radiator instead of the above-mentioned graphite sheet.

### CITATION LIST

### Patent Literature 1: Japanese Patent Application Laying-Open Publication No. 2004-288949

### SUMMARY OF THE INVENTION

### Technical Problem

As shown in FIG. 1, a conventional package includes: a conductive base plate 200: a semiconductor device (not shown) disposed on the conductive base plate 200; an insulating layer 20 disposed on the conductive base plate 200 adjoining of the semiconductor device; an input stripline 19a and an output stripline 19b disposed on the insulating layer 20; a metal wall 16a housing the semiconductor device and having a rectangular frame shape disposed on the conductive base plate 200; and a metal cap 10a disposed on the metal wall 16a, for example.

However, in the conventional package, as shown in FIG. 1, since at the conductive base plate 200 overflowing the frame of the metal wall 16a outside, the package is screwed down to a heat sink via screw holes 29a and 29b, the force for an exothermic unit to the heat sink is alleviated. Accordingly, there was a problem that sufficient heat radiation could not be performed since thermal resistance is high when radiating heat in the heat generated from the semiconductor device.

Moreover, in the above-mentioned package configuration, although it is possible of highly efficient heat radiation by attaching and disposing by inserting the graphite sheet all over the mounting side of the package base or by inserting the grease for heat radiation, it has a problem that the graphite sheets and the grease for heat radiation become an obstacle of electric conduction, and its electrical performance is reduced.

Moreover, according to the above-mentioned method, since the number of parts increase, it also has a problem that assembly fabrication is troublesome.

### Solution to Problem

According to one aspect of the present invention, a package comprises a conductive base plate; a ceramic wall configured to house a semiconductor device and a circuit board disposed adjoining of the semiconductor device, the ceramic wall configured to be disposed on the conductive base plate, the ceramic wall configured to have a frame shape having a screw hole in each of four corners; a metal seal ring configured to have a framed shape and be disposed on the ceramic wall; and a ceramic cap configured to be disposed on the metal seal ring, and wherein the ceramic wall is screwed to the conductive base plate through the screw hole.

According to another aspect of the present invention, a package comprises a frame member of a frame shape configured to be provided on a mounting base, a semiconductor device being housed and disposed in the frame member; a lid disposed on an aperture side of the frame member; and fixing means configured to press both ends opposing at least one of the lid and the frame member in a direction of the mounting base, and to perform pressure fixation of the mounting base to a radiator.

According to another aspect of the present invention, a fabrication method for a package comprises forming a conductive base plate; forming a ceramic wall having a frame shape including a screw hole in four corners on the conductive base plate, the ceramic wall housing a semiconductor device and an input circuit substrate and an output circuit substrate by adjoining of the semiconductor device; forming a metal seal ring on the ceramic wall; forming a ceramic cap on the metal seal ring; and screwing the ceramic wall to the conductive base plate through the screw hole.

### ADVANTAGEOUS EFFECTS OF INVENTION

According to the present invention, it can be provided of the package which can radiate heat satisfactory in the heat generation from the semiconductor device, and can improve reliability, and can be applied to the high frequency of the microwave/millimeter wave/sub-millimeter wave band; and the fabrication method for the same.

According to the present invention, it can be provided of the package which can achieve easy processing fabrication with the simple configuration, can achieve the highly efficient radiation characteristic, and allows securing highly precise electrical performance; and the fabrication method for the same.

### BRIEF DESCRIPTION OF DRAWINGS

FIG. 1A is a schematic bird' s-eye view for explaining a fabrication method of a conventional package, and is a schematic configuration diagram of a metal cap 10a.

FIG. 1B is a schematic bird' s-eye view for explaining the fabrication method of the conventional package, and is a schematic configuration diagram of a metal wall 16a.

FIG. 1C is a schematic bird's-eye view for explaining the fabrication method of the conventional package, and is a schematic configuration diagram of an input stripline 19a and an output stripline 19b disposed on a conductive base plate 200 and an insulating layer 20.

FIG. 2A is a schematic bird' s-eye view for explaining a fabrication method of a package according to a first embodiment of the present invention, and is a schematic configuration diagram of a ceramic cap 10.

FIG. 2B is a schematic bird' s-eye view for explaining the fabrication method of the package according to the first embodiment of the present invention, and is a schematic configuration diagram of a metal seal ring 14a having screw holes in corner parts.

FIG. 2C is a schematic bird's-eye view for explaining the fabrication method of the package according to the first embodiment of the present invention, and is a schematic configuration diagram of a ceramic wall 16 having screw holes in corner parts.

FIG. 2D is a schematic bird' s-eye view for explaining the fabrication method of the package according to the first embodiment of the present invention, and is a schematic configuration diagram of an input stripline 19a and an output stripline 19b disposed on a conductive base plate 200 and an insulating layer 20.

FIG. 3 is a schematic plane pattern configuration diagram of the package according to the first embodiment of the present invention.

FIG. 4 shows a cross-section structure of the package according to the first embodiment of the present invention, and is a schematic cross-sectional configuration diagram taken in the line I-I of FIG. 3.

FIG. 5 is a schematic plane pattern configuration diagram of a package according to a modified example 1 of the first embodiment of the present invention.

FIG. 6 is a schematic plane pattern configuration diagram of a package according to a modified example 2 of the first embodiment of the present invention.

FIG. 7 is a schematic plane pattern configuration diagram of a package according to a modified example 3 of the first embodiment of the present invention.

FIG. 8 is a schematic plane pattern configuration diagram of a package according to a modified example 4 of the first embodiment of the present invention.

FIG. 9 is an overall schematic plane pattern configuration diagram of a semiconductor device 24 applying the package according to the first embodiment and its modified examples 1 to 4.

FIG. 10 is a perspective diagram shown in order to explain a package according to a second embodiment of the present invention.

FIG. 11 is an exploded perspective diagram showing the state of separating a lid of the package of FIG. 10.

FIG. 12A is a top view showing the package of FIG. 10, and showing a state of observing from a top surface.

FIG. 12B is a top view showing the package of FIG. 10, and showing a state of observing from a side surface.

FIG. 12C is a sectional view showing the package of FIG. 10, and showing a cross section taken in the line A-A of FIG. 12A.

FIG. 13 is a perspective diagram shown in order to explain a package according to a third embodiment of the present invention.

FIG. 14 is an exploded perspective diagram showing a state of separating a lid of the package of FIG. 13.

FIG. 15 is a perspective diagram shown in order to explain a package according to a fourth embodiment of the present invention.

FIG. 16 is an exploded perspective diagram showing a state of separating a lid of the package of FIG. 15.

FIG. 17 is a perspective diagram shown in order to explain a package according to a fifth embodiment of the present invention.

FIG. 18 is a fragmentary sectional view showing a state of performing pressure fixation of the package of FIG. 17 to a heat sink.

FIG. 19 is a perspective diagram shown in order to explain a package according to a sixth embodiment of the present invention.

FIG. 20 is an exploded perspective diagram showing a state of separating a lid of the package of FIG. 19.

FIG. 21 is a top view showing a state of observing the package of FIG. 19 from a side surface.

FIG. 22 is a perspective diagram shown in order to explain a package according to a seventh embodiment of the present invention.

FIG. 23 is an exploded perspective diagram showing a state of taking out the package of FIG. 22 and separating a fixture from a surface of a lid.

FIG. 24A is a top view showing the package of FIG. 22, and showing a state of observing from a top surface.

FIG. 24B is a top view showing the package of FIG. 22, and showing a state of observing from a side surface.

FIG. 24C is a sectional view showing the package of FIG. 22, and showing a cross section taken in the line A-A of FIG. 24A.

FIG. 25 is a fragmentary sectional view shown in order to explain a package according to the eighth embodiment of the present invention.

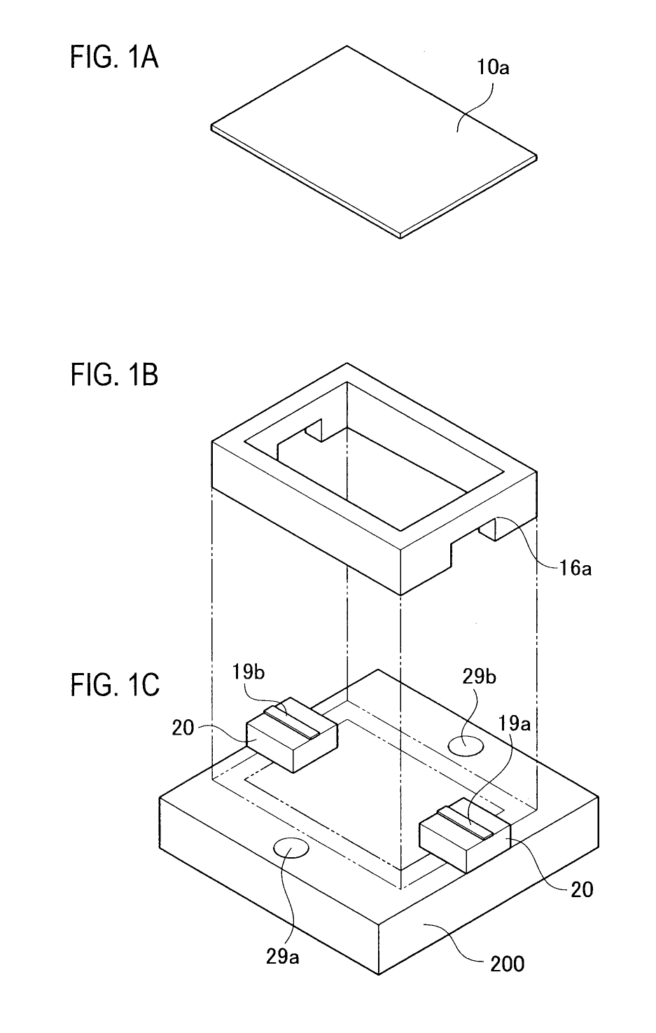

### DESCRIPTION OF EMBODIMENTS

There will be described embodiments of the present invention, with reference to the drawings, where like members or elements are designated by like reference characters to eliminate redundancy, and some package component layers and their subsidiary regions are designated by the same reference characters for simplicity. Drawings are schematic, not actual, and may be inconsistent in between in scale, ratio, etc.

The embodiments to be described are embodiments of a technical concept or spirit of the present invention that is not limited to embodied specifics, and may be changed without departing from the spirit or scope of claims.

### First Embodiment

### Package Structure

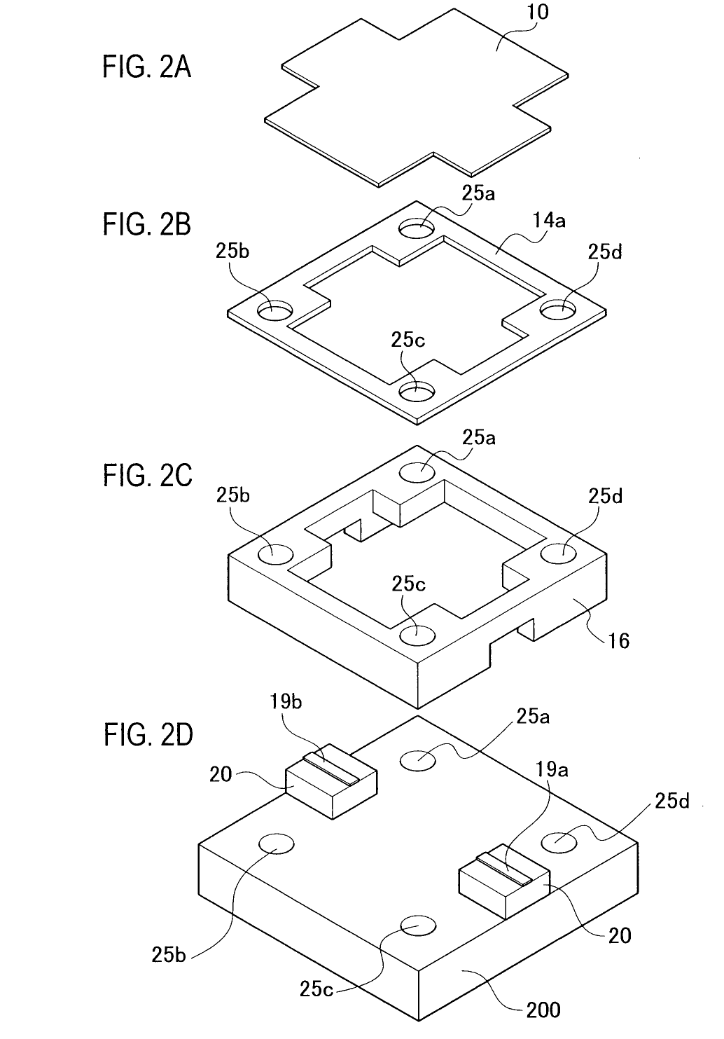

A schematic bird' s-eye view for explaining a fabrication method of a package according to a first embodiment of the present invention is expressed as shown in FIG. 2. FIG. 2A shows a schematic configuration of a ceramic cap 10. FIG. 2B shows a schematic configuration of a metal seal ring 14a having screw holes 25a to 25d in a corner part. FIG. 2C shows a schematic configuration of a ceramic wall 16 having the screw holes 25a to 25d to a corner part. FIG. 2D shows a schematic configuration of an input stripline 19a and an output stripline 19b disposed on a conductive base plate 200 and an insulating layer 20.

As shown in FIG. 2, the package according to the first embodiment includes: a ceramic cap 10 having a cross form shaped plate; a metal seal ring 14a of the framed shape having a cross type apertural area; a ceramic wall 16 of the frame shape having a cross type apertural area; and an input stripline 19a and an output stripline 19b disposed on a conductive base plate 200 and an insulating layer 20. Each of the metal seal ring 14a and the ceramic wall 16 has screw holes 25a to 25d in the corner part of four corners.

### (Conductive Base Plate 200)

The conductive base plate 200 of the package according to the first embodiment is formed with conductive metals, such as Kovar, copper, a copper tungsten alloy, a copper molybdenum alloy, and molybdenum, for example. Furthermore, electroplated conductors, such as a nickel, silver, silver-platinum alloy, a silver-palladium alloy, and gold, may be formed on the surface of the conductive base plate 200, for example.

### (Ceramic Wall 16)

The material of the ceramic wall 16 of the frame shape having cross type apertural area can form with alumina (Al₂O₃), aluminum nitride (AIN), beryllium oxide (BeO), etc., for example.

A solder metal layer (not shown) for soldering is formed on the top surface of the ceramic wall 16 via the metal seal ring 14a. The solder metal layer can form with a gold germanium alloy, a gold tin alloy, etc., for example.

Moreover, in the package according to the first embodiment, the ceramic wall 16 of the frame shape having the cross type apertural area is disposed on the conductive base plate 200 via an insulating or conductive adhesive bond. The insulating adhesive bond can form with an epoxy resin, glass, etc., for example, and the conductive adhesive bond can form with a gold germanium alloy, a gold tin alloy, etc., for example.

### (Ceramic Cap 10)

The ceramic cap 10 has a cross form shaped plate, as shown in FIG. 2.

The ceramic cap 10 of the cross form is disposed via the metal seal ring 14a on the ceramic wall 16.

As a result, as shown in FIG. 2, the package according to the first embodiment includes: the ceramic wall 16 having the cross form hollow area; the metal seal ring 14a disposed on the ceramic wall 16; and the ceramic cap having the cross form shaped plate 10 disposed on the ceramic wall 16 via the metal seal ring 14a of the framed shape having the cross type apertural area.

The semiconductor ceramic package according to the first embodiment has the high frequency characteristics of not less than 3 GHz. Accordingly, it is applicable as a device and a package for component parts of high frequency (that is, frequency over 3 GHz).

### (Plane Pattern Configuration)

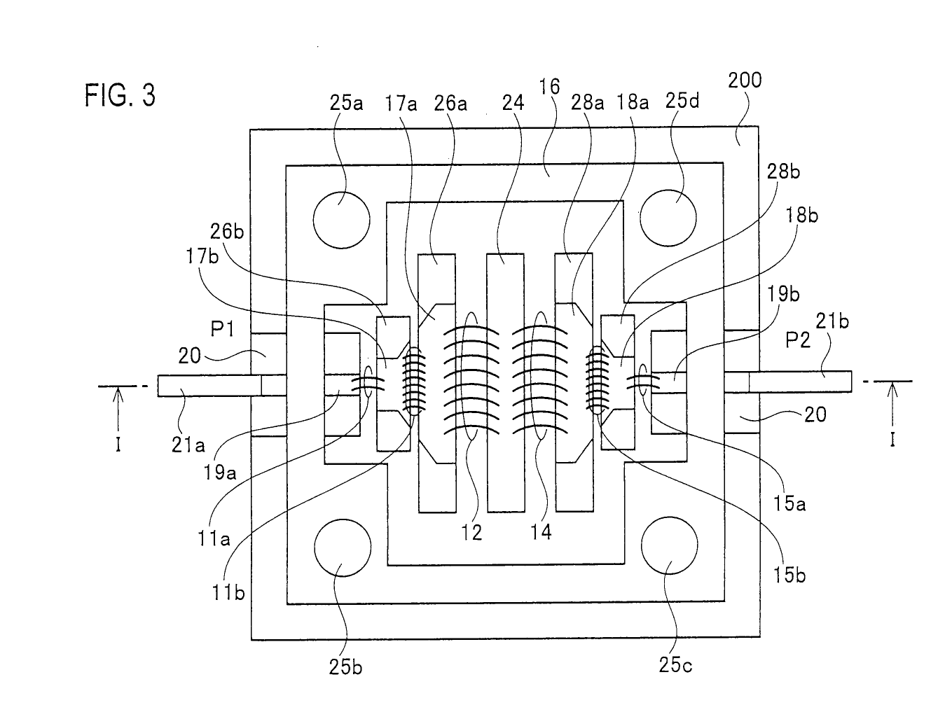

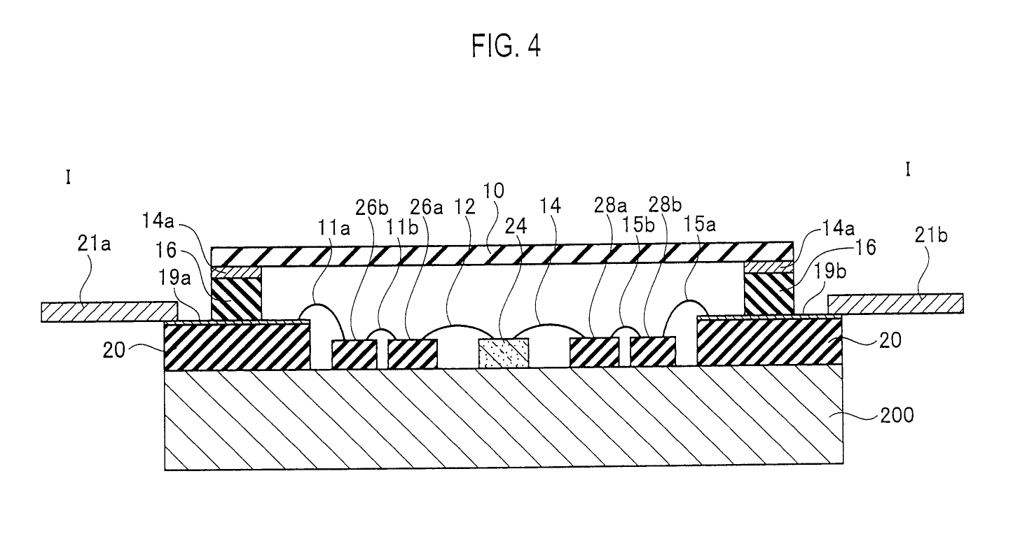

A schematic plane pattern configuration of the package according to the first embodiment is expressed as shown in FIG. 3. Moreover, a schematic cross-section structure taken in the line I-I of FIG. 3 is expressed as shown in FIG. 4.

As shown in FIG. 2 to FIG. 4, for example, a configuration of the package according to the first embodiment includes: the conductive base plate 200; a semiconductor device 24 disposed on the conductive base plate 200; input circuit substrates 26a and 26b and output circuit substrates 28a and 28b which are adjoining of the semiconductor device 24 and are disposed on the conductive base plate 200; the ceramic wall 16 which is housing the semiconductor device 24, the input circuit substrates 26a and 26b, and the output circuit substrates 28a and 28b, disposed on the conductive base plate 200, and provided with the frame shape having the screw holes 25a to 25d in the four corners; a metal seal ring 14a which is having the framed shape and is disposed on the ceramic wall 16; and a ceramic cap 10 disposed on the metal seal ring 14a. The ceramic wall 16 is screwed to the conductive base plate 200 through the screw holes 25a to 25d.

Moreover, as shown in FIG. 2 to FIG. 4, in the input/output unit of the ceramic wall 16, it includes: the insulating layer 20 disposed on the conductive base plate 200; the input stripline 19a and the output stripline 19b disposed on the insulating layer 20; an input matching circuit 17b disposed on the input circuit substrate 26b, and connected to the input stripline 19a via a bonding wire 11a; an input matching circuit 17a disposed on the input circuit substrate 26a, and connected to the input matching circuit 17b; an output matching circuit 18b disposed on the output circuit substrate 28b, and connected to the output stripline 19b via a bonding wire 15a; an output matching circuit 18a disposed on the output circuit substrate 28a, and connected to the output matching circuit 18b; a bonding wire 12 for connecting the input matching circuit 17a with the semiconductor device 24; and a bonding wire 14 for connecting the output matching circuit 18a with the semiconductor device 24.

Moreover, as shown in FIG. 3, it is connected between the input matching circuits 17a and 17b via a bonding wire 11b, and is connected between the output matching circuits 18a and 18b via a bonding wire 15b.

Moreover, as shown in FIG. 2 to FIG. 4, the ceramic wall 16 has the cross-shaped hollow area by forming the corner part of frame shape thickly.

Moreover, as shown in FIG. 3 to FIG. 4, a terminal electrode 21a acting as an input terminal P1 and a terminal electrode 21b acting as an output terminal P2 are connected to the input stripline 19a and the output stripline 19b, respectively.

Moreover, although the ceramic cap 10 having the shaped plate is disposed on the ceramic wall 16 having frame shape via the metal seal ring 14a as shown in FIG. 4, the illustration is omitted in FIG. 3.

The conductive base plate 200 is formed, for example with Cu, and the input circuit substrates 26a and 26b and the output circuit substrates 28a and 28b are formed with alumina.

According to the package according to the first embodiment, the frame shape of the ceramic wall 16 can be directly screw-fastened to the conductive base plate 200 by applying the shape of the hollow area as the cross and forming the corner part of the frame shape of the ceramic wall 16 thickly. Accordingly, the vertical axis force occurred by the screw fastening can be directly transferred between the semiconductor device 24 and the conductive base plate 200 as vertical axis force for forcing an exothermic unit on a heat sink, without alleviating. In particular accordingly, the heat can be radiated satisfactory in the heat generation from the semiconductor device 24.

### (Fabrication Method of Package)

As shown in FIG. 2 to FIG. 4, the fabrication method of the package according to the first embodiment includes: forming the conductive base plate 200; forming the semiconductor device 24 on the conductive base plate 200; forming the input circuit substrates 26a and 26b and the output circuit substrates 28a and 28b on the conductive base plate 200 by adjoining of the semiconductor device 24; forming the ceramic wall 16 having the screw holes 25a to 25d in the four corners and having the frame shape on the conductive base plate 200, housing the semiconductor device 24, the input circuit substrates 26a and 26b, and the output circuit substrates 28a and 28b; forming the metal seal ring 14a on the ceramic wall 16; forming the ceramic cap 10 on the metal seal ring 14a; and screwing the ceramic wall 16 to the conductive base plate 200 through the screw holes 25a to 25d.

Moreover, as shown in FIG. 2 to FIG. 4, in the input/output unit of the ceramic wall 16, the fabrication method of the package according to the first embodiment includes: forming the insulating layer 20 on the conductive base plate 200; forming the input stripline 19a and the output stripline 19b on the insulating layer 20; forming the input matching circuit 17b connected to the input stripline 19a on the input circuit substrate 26b; forming the output matching circuit 18b connected to the output stripline 19b on the output circuit substrate 28b; forming the input matching circuit 17a connected to the input matching circuit 17b on the input circuit substrate 26a; forming the output matching circuit 18a connected to the output circuit substrate 28b on the output circuit substrate 28a; connecting the input matching circuit 17a with the semiconductor device 24 using the bonding wire 12; and connecting the output matching circuit 18a with the semiconductor device 24 using the bonding wire 14.

Moreover, the fabrication method of the package according to the first embodiment includes: connecting the input matching circuit 17a and the input matching circuit 17b using the bonding wire 11b; and connecting the output matching circuit 18a and the output matching circuit 18b using the bonding wire 15b.

Moreover, the fabrication method of the package according to the first embodiment includes: connecting the input matching circuit 17b and the input stripline 19a using the bonding wire 11a; and connecting the output matching circuit 18b and the output stripline 19b using the bonding wire 15a.

According to the first embodiment, it can be provided of the package which can radiate heat satisfactory in the heat generation from the semiconductor device, and can improve reliability, and can be applied to the high frequency of the microwave/millimeter wave/sub-millimeter wave band; and the fabrication method for the same.

### Modified Example 1 of First Embodiment

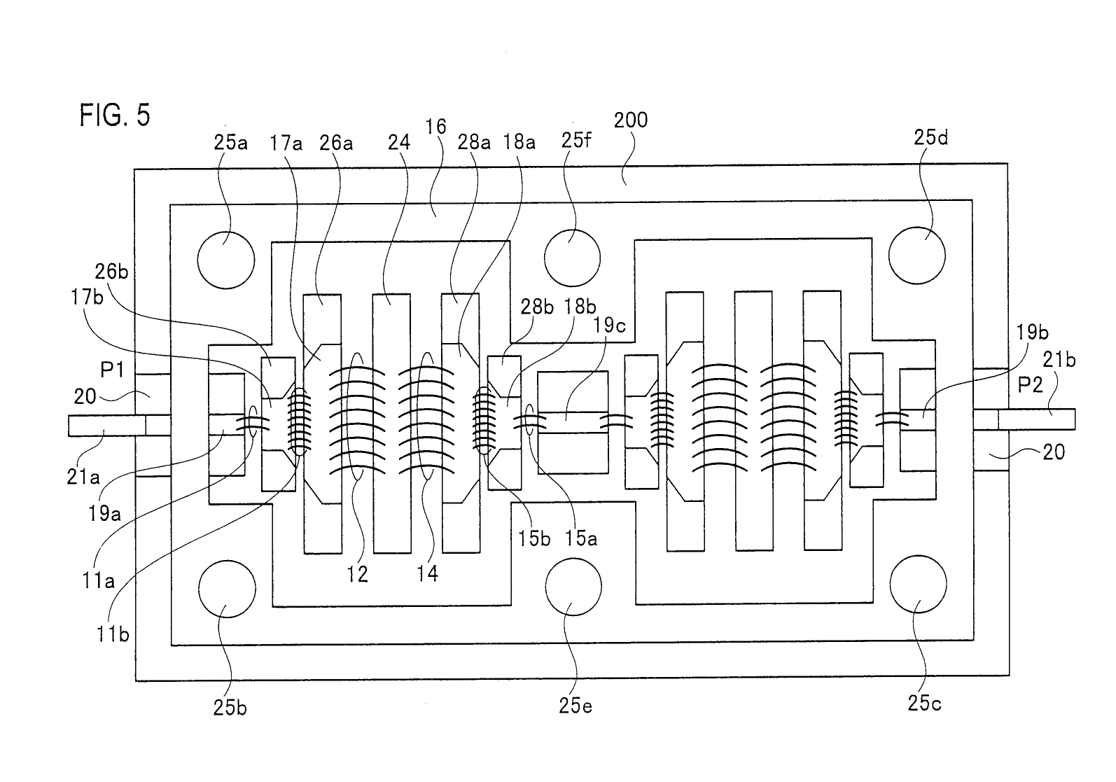

As shown in FIG. 5, a schematic plane pattern configuration of a package according to the modified example 1 of the first embodiment is composed of two stage constitution of amplifiers. A first stage amplifier includes: a conductive base plate 200; a semiconductor device 24 disposed on the conductive base plate 200; and an input circuit substrates 26a and 26b and the output circuit substrates 28a and 28b disposed on the conductive base plate 200, adjoining of the semiconductor device 24. A second stage amplifier is also provided with the same configuration. As shown in FIG. 5, a stripline 19c is disposed at the connected portion between the first stage amplifier and the second stage amplifier, and the stripline 19c connects an output matching circuit 18b of the first stage amplifier and an input matching circuit 17b of the second stage amplifier.

As shown in FIG. 5, a package according to the modified example 1 of the first embodiment includes: the conductive base plate 200; a plurality of semiconductor devices 24 disposed on the conductive base plate 200; a plurality of input circuit substrates 26a and 26b and a plurality of output circuit substrates 28a and 28b disposed on the conductive base plate 200, adjoining of a plurality of semiconductor devices 24; and a ceramic wall 16 which is provided with the frame shape and having the screw holes 25e and 25f and 25a to 25d in the central part and the four corners of a long side, respectively, is disposed on the conductive base plate 200, and is housing a plurality of semiconductor devices 24, a plurality of input circuit substrates 26a and 26b, and a plurality of output circuit substrates 28a and 28b. In FIG. 5, the metal seal ring disposed on the ceramic wall 16 and the ceramic cap disposed on the metal seal ring are omitting illustrations.

In the package according to the modified example 1 of the first embodiment, as shown in FIG. 5, the ceramic wall 16 is screwed to the conductive base plate 200 through the screw holes 25e and 25f and 25a to 25d.

The package according to the modified example 1 of the first embodiment has a configuration by which the plane pattern configuration of FIG. 3 is disposed continuously, as shown in FIG. 5. Since it is only that the structures disposed continuously differ in this manner, and the configuration of other details is the same as that of the first embodiment, the duplicate explanation is omitted. Moreover, since the fabrication method of the package according to the modified example of the first embodiment is the same as that of the first embodiment, the duplicate explanation is omitted.

In the package according to the modified example 1 of the first embodiment, the ceramic wall 16 is has the continuous cross type hollow area by forming the central part and the corner part of the long side of frame shape thickly.

Moreover, in the package according to the modified example 1 of the first embodiment, the ceramic wall 16 may be include the polygonal shape hollow area by forming the central part and the corner part of the long side of frame shape thickly, and forming the short side part of frame shape in linear shape, as well as the modified example 2 described later.

Moreover, in the package according to the modified example 1 of the first embodiment, the ceramic wall 16 may be include the hollow area by forming the corner part of frame shape in the curve profile thickly, and forming the short side part of frame shape in linear shape, as well as the modified example 3 or the modified example 4 described later.

According to the package according to the modified example 1 of the first embodiment, the frame shape of the ceramic wall 16 can be directly screw-fastened to the conductive base plate 200 in the central part and the corner part of the long side by applying shape of the hollow area of the ceramic wall 16 as the continuous cross form, and forming thickly the central part and the corner part of the long side of frame shape. Accordingly, the vertical axis force occurred by the screw fastening can be directly transferred between the semiconductor device 24 and the conductive base plate 200 as vertical axis force for forcing an exothermic unit on a heat sink, without alleviating. In particular accordingly, the heat can be radiated satisfactory in the heat generation from a plurality of semiconductor devices 24.

According to the modified example 1 of the first embodiment, it can be provided of the package which can radiate heat satisfactory in the heat generation from a plurality of semiconductor devices, and can improve reliability, and can be applied to the high frequency of the microwave/millimeter wave/sub-millimeter wave band; and the fabrication method for the same.

### Modified Example 2 of First Embodiment

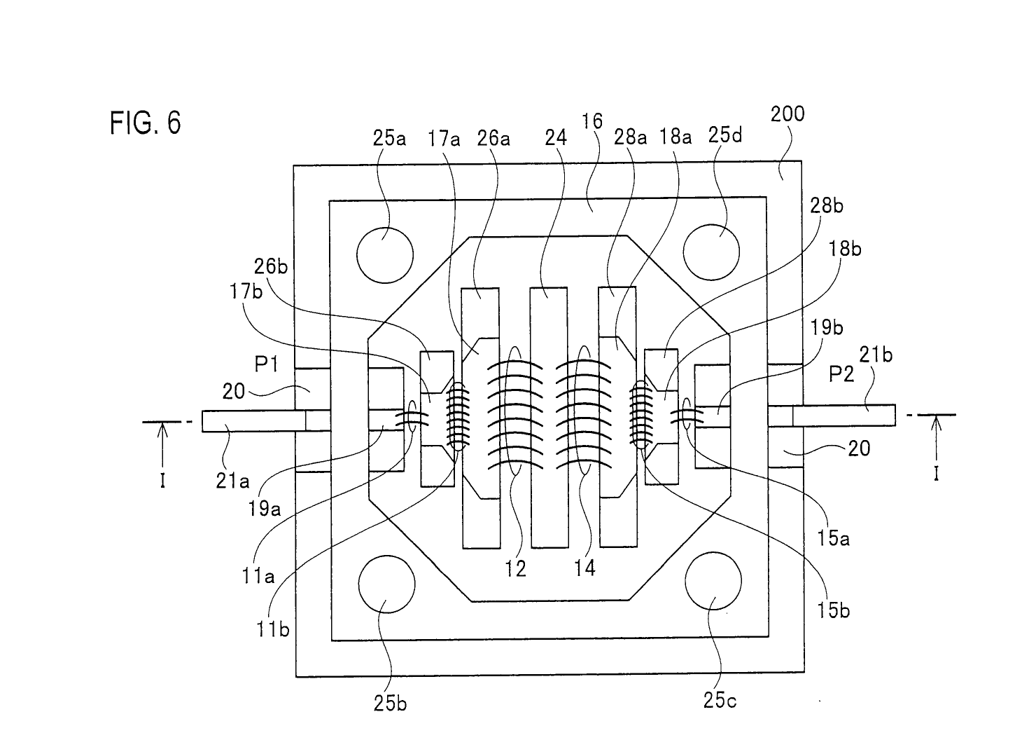

A schematic plane pattern configuration of a package according to a modified example 2 of the first embodiment is expressed as shown in FIG. 6.

In the package according to the modified example 2 of the first embodiment, the ceramic wall 16 has a polygonal shape hollow area by forming the corner part of frame shape thickly, and forming the side part of frame shape in linear shape.

Since it is only that the configuration of the package according to the modified example 2 of the first embodiment differs in the shape of the ceramic wall 16, and other configurations are the same as that of the first embodiment, the duplicate explanation is omitted.

The polygon may be any one of a hexagon or an octagon.

According to the package according to the modified example 2 of the first embodiment, as for the shape of the hollow area of the ceramic wall 16, the frame shape of the ceramic wall 16 can be directly screw fastened to the conductive base plate 200 in the corner part by composing of the polygon by forming the corner part of frame shape thickly, and forming the side part of frame shape in linear shape. Accordingly, the vertical axis force occurred by the screw fastening can be directly transferred between the semiconductor device 24 and the conductive base plate 200 as vertical axis force for forcing an exothermic unit on a heat sink, without alleviating. In particular accordingly, the heat can be radiated satisfactory in the heat generation from the semiconductor device 24.

According to the modified example 2 of the first embodiment, it can be provided of the package which can radiate heat satisfactory in the heat generation from the semiconductor device, and can improve reliability, and can be applied to the high frequency of the microwave/millimeter wave/sub-millimeter wave band; and the fabrication method for the same.

### Modified Example 3 of First Embodiment

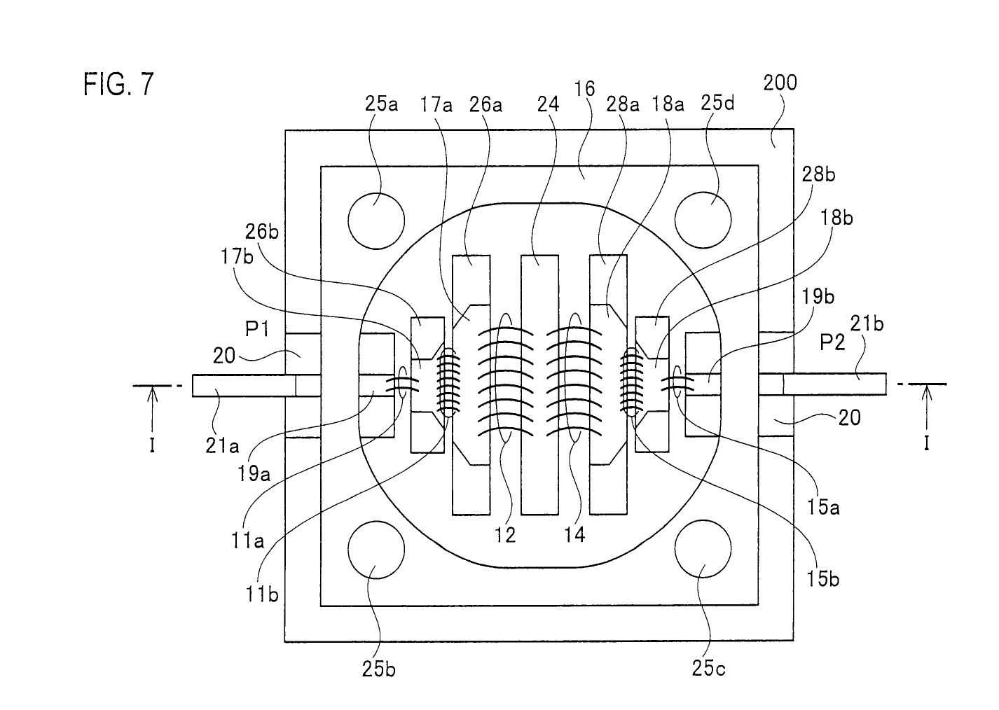

A schematic plane pattern configuration of a package according to a modified example 3 of the first embodiment is expressed as shown in FIG. 7.

In the package according to the modified example 3 of the first embodiment, the ceramic wall 16 has a hollow area by forming the corner part of frame shape in the curve profile thickly, and forming the side part of frame shape in linear shape.

Since it is only that the configuration of the package according to the modified example 3 of the first embodiment differs in the shape of the ceramic wall 16, and other configurations are the same as that of the first embodiment, the duplicate explanation is omitted.

According to the package according to the modified example 3 of the first embodiment, as for the shape of the hollow area of the ceramic wall 16, the frame shape of the ceramic wall 16 can be directly screw fastened to the conductive base plate 200 in the corner part by forming the corner part of frame shape in the curve profile thickly, and forming the side part of frame shape in the linear shape. Accordingly, the vertical axis force occurred by the screw fastening can be directly transferred between the semiconductor device 24 and the conductive base plate 200 as vertical axis force for forcing an exothermic unit on a heat sink, without alleviating. In particular accordingly, the heat can be radiated satisfactory in the heat generation from the semiconductor device 24.

According to the modified example 3 of the first embodiment, it can be provided of the package which can radiate heat satisfactory in the heat generation from the semiconductor device, and can improve reliability, and can be applied to the high frequency of the microwave/millimeter wave/sub-millimeter wave band; and the fabrication method for the same.

### Modified Example 4 of First Embodiment

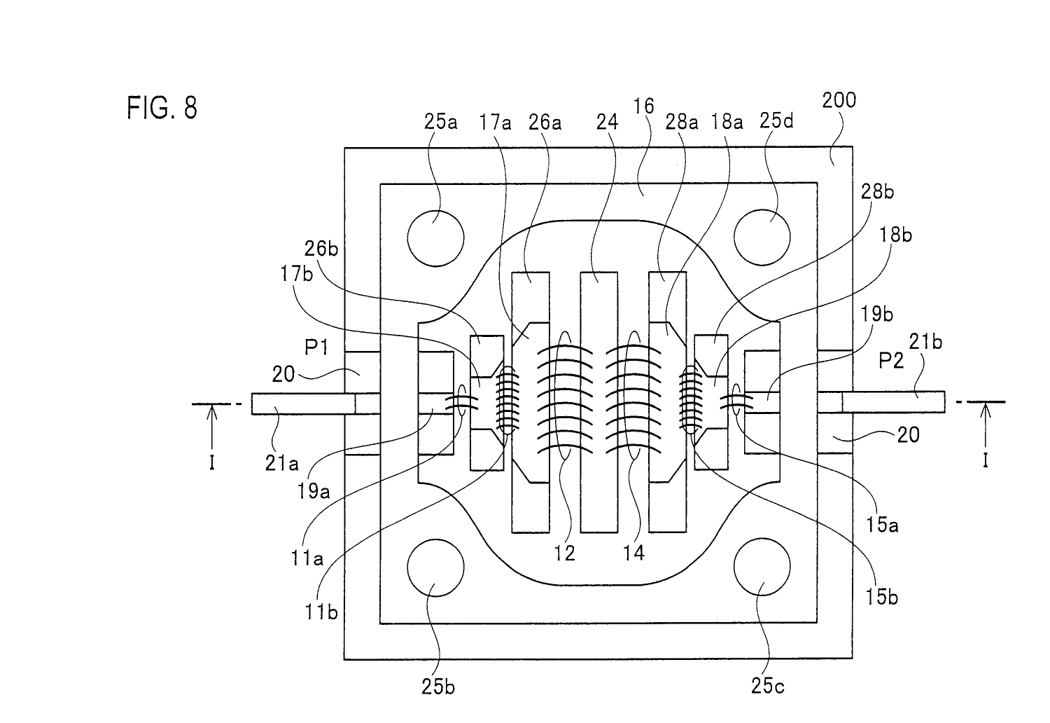

A schematic plane pattern configuration of a package according to a modified example 4 of the first embodiment is expressed as shown in FIG. 8.

In the package according to the modified example 4 of the first embodiment, as shown in FIG. 8, the ceramic wall 16 has a hollow area by forming the corner part of frame shape in the curve profile thickly, and forming the side part of frame shape in linear shape.

Since it is only that the configuration of the package according to the modified example 4 of the first embodiment differs in the shape of the ceramic wall 16, and other configurations are the same as that of the first embodiment, the duplicate explanation is omitted.

According to the package according to the modified example 4 of the first embodiment, as for the shape of the hollow area of the ceramic wall 16, the frame shape of the ceramic wall 16 can be directly screw fastened to the conductive base plate 200 in the corner part by forming the corner part of frame shape in the curve profile thickly, and forming the side part of frame shape in the linear shape. Accordingly, the vertical axis force occurred by the screw fastening can be directly transferred between the semiconductor device 24 and the conductive base plate 200 as vertical axis force for forcing an exothermic unit on a heat sink, without alleviating. In particular accordingly, the heat can be radiated satisfactory in the heat generation from the semiconductor device 24.

According to the modified example 4 of the first embodiment, it can be provided of the package which can radiate heat satisfactory in the heat generation from the semiconductor device, and can improve reliability, and can be applied to the high frequency of the microwave/millimeter wave/sub-millimeter wave band; and the fabrication method for the same.

### (Pattern Configuration of Semiconductor Device)

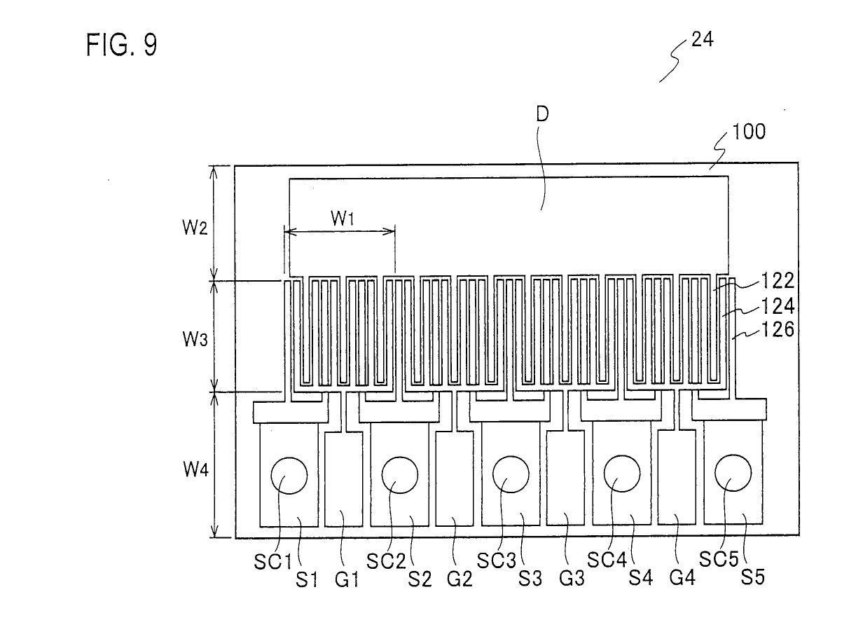

As shown in FIG. 9, an overall schematic plane pattern configuration of the semiconductor device 24 applying the package according to the first embodiment and its modified examples 1 to 4 includes: a substrate 100; a gate electrode 124, a source electrode 126, and a drain electrode 122 which are disposed on a first surface of the substrate 100 and have a plurality of fingers, respectively; and gate terminal electrodes G1, G2, . . . , G4, source terminal electrodes S1, S2, . . . , S5, and a drain terminal electrode D which are disposed on the first surface of the substrate 100 and tie a plurality of fingers, respectively every the gate electrode 124, the source electrode 126, and the drain electrode 122.

In the configuration example of FIG. 9, as for the size of each part, the cell width W1 is about 120 μm, for example, W2 is about 80 μm, the cell length W3 is about 100 μm, W4 is about 120 μm, and the gate width is about 100 μm×6×4 cell=2.4 mm as a whole.

In the example of FIG. 9, in the source terminal electrodes S1 to S5, VIA holes SC1 to SC5 are formed from the back side of the substrate 100, and a ground conductor is formed on the back side of the substrate 100. And when grounding a circuit element, the circuit element provided on the substrate 100 and the ground conductor formed on the back side of the substrate 100 are electrically connected via the VIA holes SC1 to SC5 which pass through the semiconductor substrate 100.

The substrate 100 may be provided with either of an SiC substrate, a GaAs substrate, a GaN substrate, a substrates in which the GaN epitaxial layer is formed on the SiC substrate, a substrate in which a heterojunction epitaxial layer composed of GaN/AlGaN is formed on the SiC substrate, a substrate in which a GaN epitaxial layer is formed on a sapphire substrate, a sapphire substrate or a diamond substrate, for example.

The gate terminal electrodes G1 to G4 are connected to the input matching circuit 17a disposed around the semiconductor device 24 by the bonding wire 12, for example. Similarly, the drain terminal electrode D is connected to the output matching circuit 18a disposed around the semiconductor device 24 by the bonding wire 14, for example.

### Second Embodiment

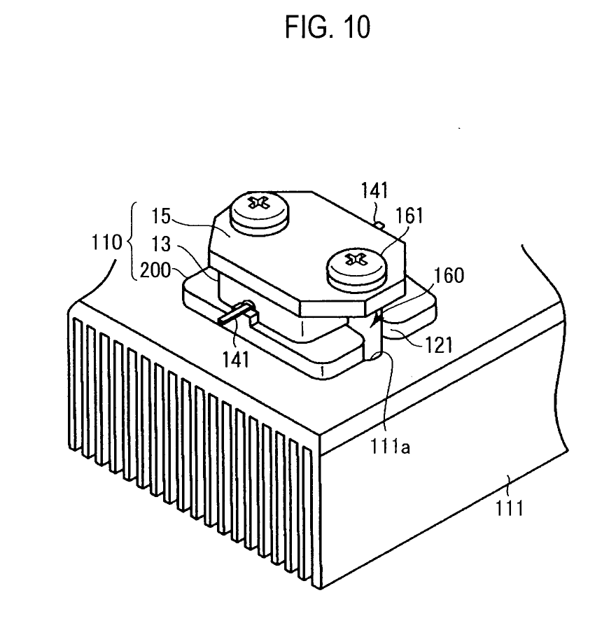

FIG. 10 shows an appearance configuration of a package 110 according to a second embodiment, the package 110 is disposed by connecting thermally on a heat sink 111 which is a radiator.

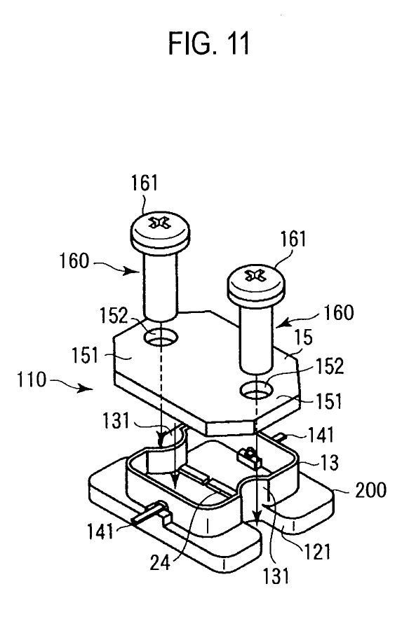

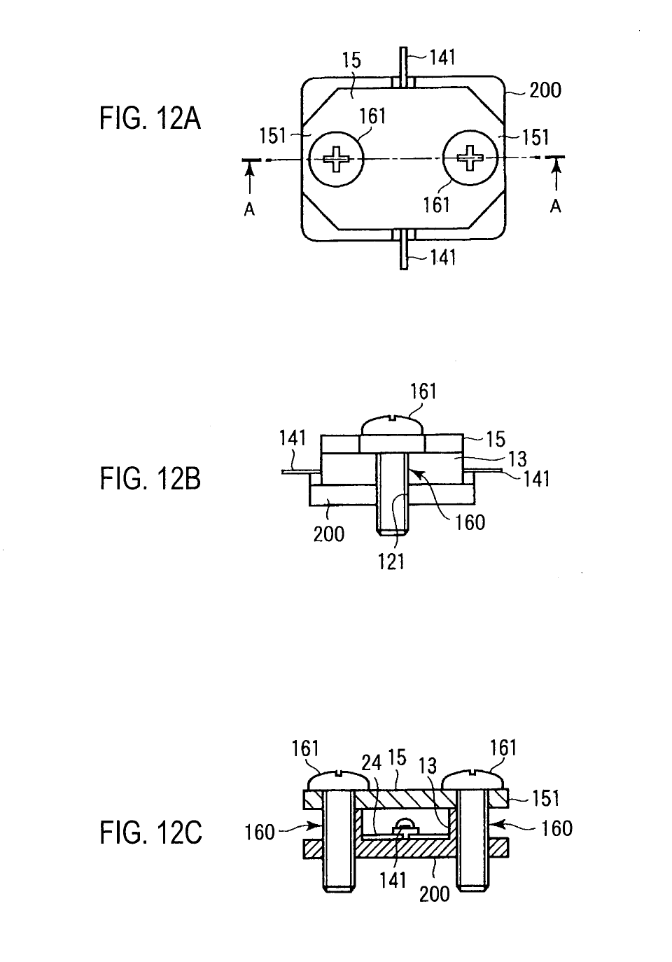

As shown, for example in FIG. 11 and FIG. 12, as for the package 110, a frame member 13 of a frame shape composing a device including part is integrally provided on a conductive base plate 200 of a rectangular shape which is a mounting base made from metallic materials, such as a copper alloy excellent in thermal conductivity. A recessed region for mounting 121 is provided in the both ends opposing at the conductive base plate 200.

A semiconductor device 24 which is a heating element is housed and disposed in the frame member 13, and external connection terminals 141 electrically connected to the semiconductor device 24 is provided in an extended condition by opposing each side walls in which the recessed region for mounting 121 of the conductive base plate 200 does not exist, respectively.

A concave engagement unit 131 is formed on the opposing each side walls of the frame member 13 in which the external connection terminal 141 does not exist, for example as a rigid body part corresponding to the recessed region for mounting 121 of the conductive base plate 200, respectively.

Moreover, a lid 15 made from a metallic material, for example, is disposed on an aperture side of the frame member 13, and the aperture is sealed. A pressing unit 151 is installed in the opposing both sides part in the lid 15, respectively. An insertion hole 152 is formed in the pressing unit 151 corresponding to the engagement unit 131 of the frame member 13, respectively.

A screw member 160 composing a fixing means is inserted in the insertion hole 152 of the lid 15 disposed on the frame member 13. The screw member 160 is guided along with the engagement unit 131 of the frame member 13, is inserted in the recessed region for mounting 121 of the conductive base plate 200, and then is screwed in the screw hole 111a provided in the heat sink 111.

As for the screw member 160, the end face side of a head 161 opposes the edge side of the engagement unit 131 of the frame member 13 via the pressing unit 151 of the lid 15. When the screw member 160 is fastened to a screw hole 111a of the heat sink 111, the end face side of the head 161 presses the pressing unit 151 of the lid 15, and presses the perimeter of the engagement unit 131 of the frame member 13 in the base plate 200 direction (refer to FIG. 12C).

Accordingly, the pressure fixation of the whole surface of the mounting face including the region surrounded by the frame member 13 of the conductive base plate 200 is performed on the heat sink 111 in equivalent, and the heat couplings of the whole surface are performed to the heat sink 111.

According to the above-mentioned configuration, the mounting face side of the conductive base plate 200 is mounted on the heat sink 111 in the state where the lid 15 is disposed on the aperture side of the frame member 13, and the insertion hole 152 of the pressing unit 151 of the lid 15 opposes the screw hole 111a of the heat sink 111. In the state where the conductive base plate 200 is mounted on the heat sink 111, the screw member 160 is inserted in the insertion hole 152 of the lid 15, and the tip region of the screw member 160 is fastened by being screwed in the screw hole 111a of the heat sink 111.

The screw member 160 presses the perimeter of the engagement unit 131 of the frame member 13 in the direction of the base, by pressing the end face side of the head 161 to the pressing unit 151 of the lid 15. Accordingly, the whole surface of the mounting face of the conductive base plate 200 including the region surrounded by the frame member 13 is contacted by pressure to the heat sink 111 in equivalent, and the heat couplings of the package 110 are performed to the heat sink 111.

As for the package 110, the external connection terminal 141 provided in an extended condition from the wall surface of the frame member 13 is electrically connected to the connecting end of a printed wiring board (not shown). As for the package 110, the conductive base plate 200 has small thermal resistance characteristics for the heat sink 111, and the heat couplings are performed. Accordingly, the electrical connection of high quality for the heat sink 111 is obtained, and desired electrical performance is obtained.

Accordingly, when the semiconductor device 24 in the frame member 13 drives and generates heat, the thermal control of the package 110 is performed to the heat sink 111 by performing a heat transfer from the whole surface of the mounting face of the conductive base plate 200 including the region surrounded by the frame member 13.

Thus, the package 110 according to the second embodiment is composed so that pressure fixation of the conductive base plate 200 of the package 110 may be performed on the heat sink 111 and then the heat couplings may be performed, by pressing the opposing both ends where the lid 15 disposed on the frame member 13 by which the semiconductor device 24 is housed and disposed in the conductive base plate 200 direction.

According to the package 110 according to the second embodiment, the pressure fixation of the whole mounting face of the conductive base plate 200 can be performed in equivalent to the heat sink 111, without being influenced by the accuracy of finishing of the package 110, by pressing the opposing both ends of the lid 15 in the conductive base plate 200 direction, and pressing the region surrounded by the frame member 13 in which the semiconductor device 24 of the conductive base plate 200 is housed.

As a result, the reduction of contact thermal resistance can be achieved easily, it becomes possible to achieve the high-efficiency of the radiation characteristic, and it is possible of alleviating of the accuracy of finishing on the package fabrication, and facilitating of the processing fabrication including assembling work can be achieved.

Moreover, according to the package 110 according to the second embodiment, the reduction of contact thermal resistance can be achieved and the high-efficiency of the radiation characteristic can be achieved, without using different parts, such as a graphite sheet for heat radiation, and grease for heat radiation, as conventional.

Accordingly, the electrical performance of the package 110 of high quality can be secured, and easy fabrication assembling work is achieved, and it becomes possible to also achieve diversification of the specification.

According to the above-mentioned configuration, as for the mounting base, the opposing both ends at least of the lid or the frame member is pressed in the direction of the base by the fixing means, the region surrounded by the frame member in which the semiconductor device is housed is pressed, and the pressure fixation of the region is performed to the radiator. Accordingly, the whole mounting face of the mounting base is pressed for the radiator in equivalent, and the contact thermal resistance is set up on a small scale. Therefore, the simple and easy processing fabrication including assembling work is achieved, and it is possible of securing of the highly efficient radiation characteristic and highly precise electrical performance.

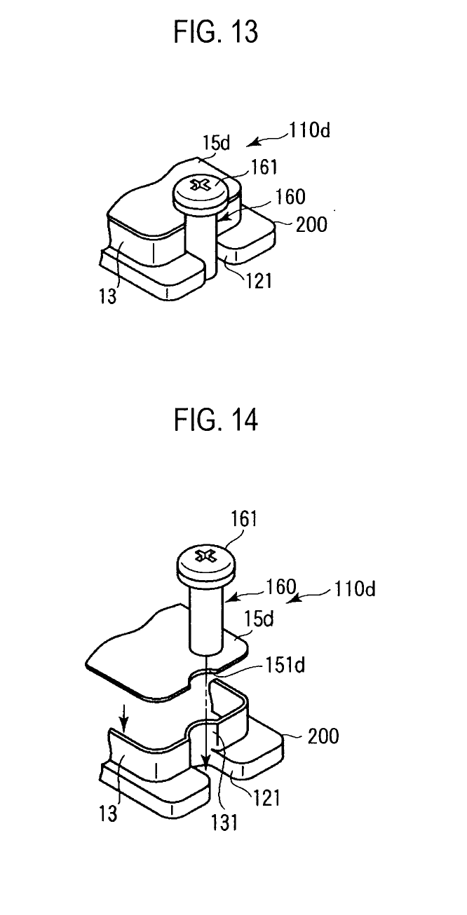

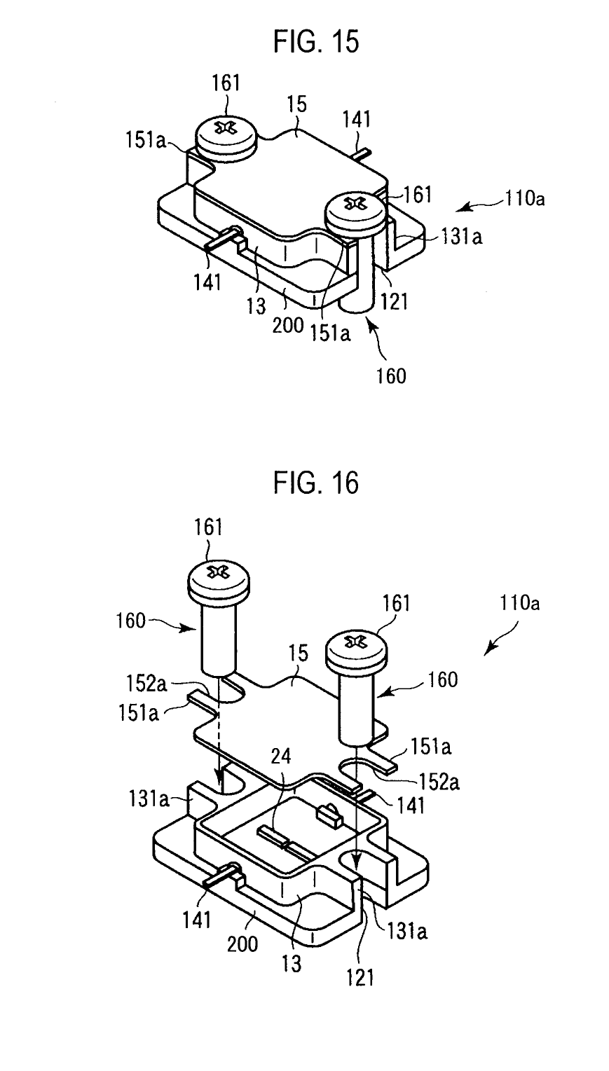

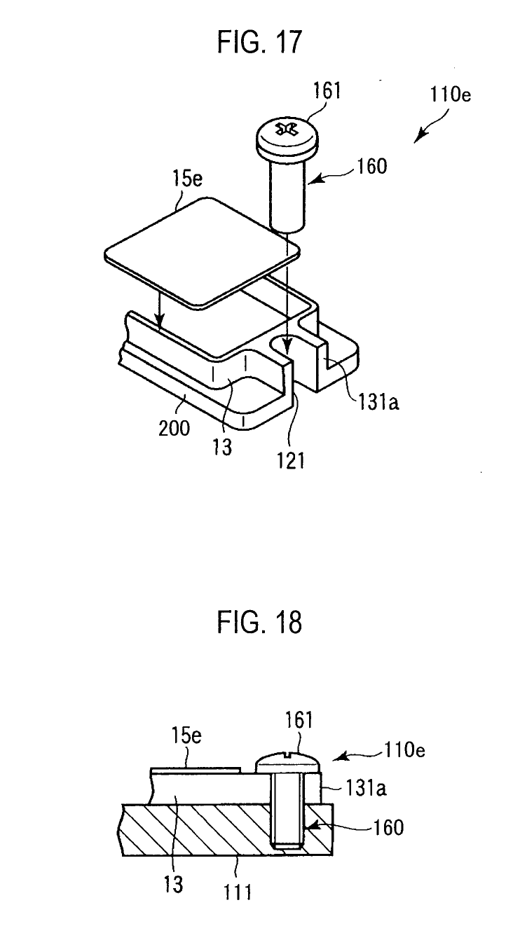

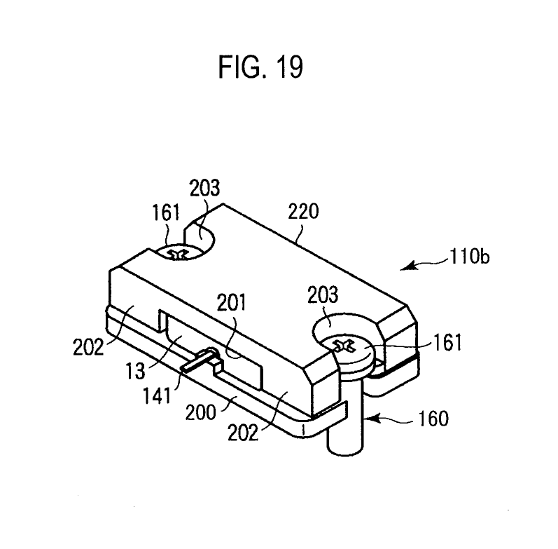

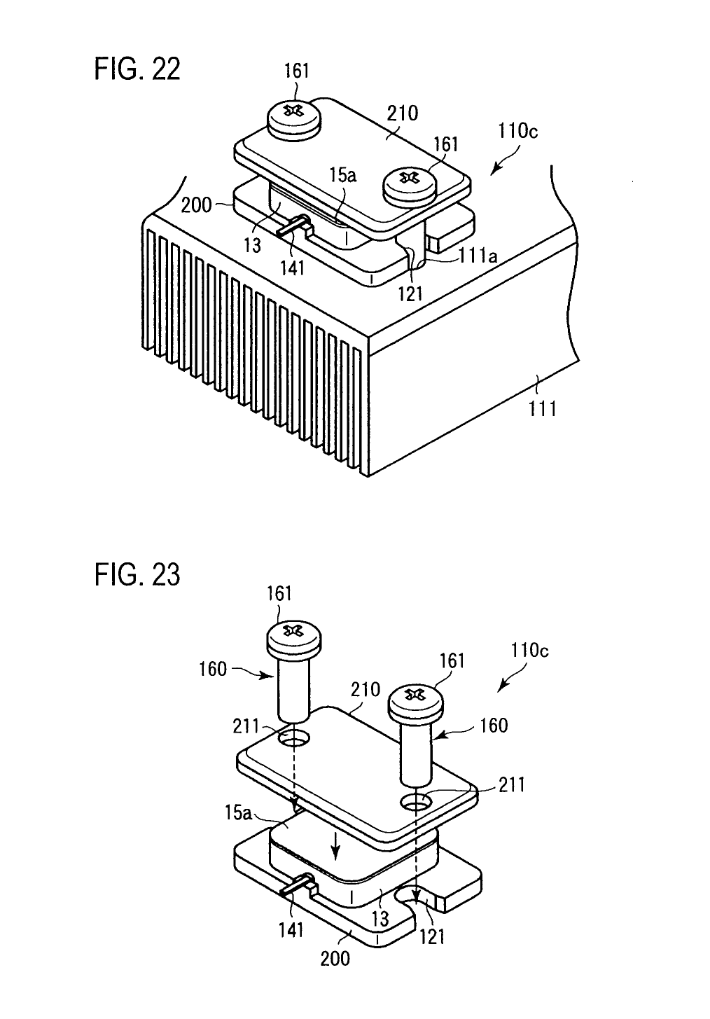

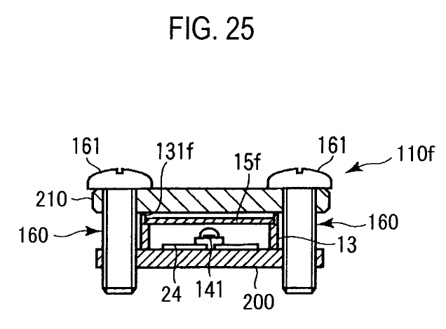

In addition, not only the above-mentioned embodiment but the present invention can be composed as shown in a third embodiment shown in FIG. 13 and FIG. 14, a fourth embodiment shown in FIG. 15 and FIG. 16, a fifth embodiment shown in FIG. 17 and FIG. 18, a sixth embodiment shown in FIG. 19 to FIG. 21, a seventh embodiment shown in FIG. 22 to FIG. 24, or a eighth embodiment shown in FIG. 25, and the available effect is expected similarly. However, in each embodiment shown in this FIG. 13 to FIG. 25, the same reference numeral is attached to the same part as above-mentioned FIG. 10 to FIG. 12, and the detailed explanation is omitted.

### Third Embodiment

As shown in FIG. 13 and FIG. 14, as for a package 110d according to a third embodiment, a lid 15d is substantially formed in same shape as the aperture side of the frame member 13, and a recessed region 151d is formed in the opposing both ends in the lid 15d corresponding to the engagement unit 131 of the frame member 13. The lid 15d is disposed on the aperture of the frame member 13 so that the recessed region 151d may be accorded in the engagement unit 131 of the frame member 13.

As for the package 110d according to the third embodiment, the conductive base plate 200 is mounted on the heat sink 111, the screw member 160 is inserted in the recessed region for mounting 121 of the conductive base plate 200 along with the recessed region 151d of the lid 15d and the engagement unit 131 of the frame member 13, and is screwed in the heat sink 111.

As for the screw member 16, the end face side of the head 161 presses the perimeter for the recessed region 151d of the lid 15, presses the perimeter of the engagement unit 131 of the frame member 13 in the conductive base plate 200 direction, and performs pressure fixation the whole surface of a mounting face including the region surrounded by the frame member 13 of the conductive base plate 200 on the heat sink 111 in equivalent and performs the heat couplings to the heat sink 111.

### Fourth Embodiment

As shown in FIG. 15 and FIG. 16, as for a package 110a according to a fourth embodiment, a convex pressing unit 151a is provided in an extended condition by the opposing both ends of the lid 15, respectively, and a recessed region 152a is formed in each end of a pressing unit 151a, respectively, as well as the third embodiment. As for the frame member 13, a concave protruding engagement unit 131a which is a rigid body part is provided in the opposing both walls corresponding to the pressing unit 151a and the recessed region 152a of the lid 15.

The protruding engagement unit 131a of the frame member 13 is disposed by being inserted to between the recessed region 152a of the pressing unit 151a of the lid 15 disposed on the aperture side, and the recessed region for mounting 121 of the conductive base plate 200. The screw member 160 inserted in the recessed region 152a of the pressing unit 151a of the lid 15 is inserted in the screw hole 111a of the heat sink 111 through the recessed region for mounting 121 of the conductive base plate 200.

When the end face side of the head 161 is engaged to the perimeter of the recessed region 152a of the pressing unit 151a of the lid 15 and is fastened by the screw hole 111a of the heat sink 111, the screw member 160 opposes the protruding engagement unit 131a of the frame member 13, presses the protruding engagement unit 131a in the conductive base plate 200 direction, and performs the pressure fixation of the conductive base plate 200 to the heat sink 111.

According to the above-mentioned configuration, when performing the pressure fixation of the package 110a according to the fourth embodiment to the heat sink 111, the conductive base plate 200 is mounted in the predetermined position on the heat sink 111, the screw member 160 is inserted in the recessed region 152a of the pressing unit 151a of the lid 15, is inserted in the protruding engagement unit 131a of the frame member 13, and the recessed region for mounting 121 of the conductive base plate 200, and is attached tightly by screwing in the screw hole 111a of the heat sink 111.

As for the package 110a according to the fourth embodiment, the pressing unit 151a of the lid 15 is pressed in the conductive base plate 200 direction by the head 161 of the screw member 160, and the protruding engagement unit 131a of the frame member 13 is pressed in the same direction.

In the package 110a according to the fourth embodiment, the whole mounting face including the region of the frame member 13 of the conductive base plate 200 is pressed in equivalent in the conductive base plate 200 direction, the pressure fixation of the whole mounting face is performed to the heat sink 111, and the heat couplings of the whole mounting face is performed with the heat sink 111.

### Fifth Embodiment

As shown in FIG. 17 and FIG. 18, a concave protruding engagement unit 131a which is a rigid body part is provided in the opposing both walls of the frame member 13 in a package 110e according to a fifth embodiment, as well as the fourth embodiment. A lid 15e is formed in quadrilateral shape corresponding to the aperture of the frame member 13, and is disposed so that the aperture of the frame member 13 may be sealed.

The protruding engagement unit 131a of the frame member 13 is disposed by opposing to the recessed region for mounting 121 of the conductive base plate 200, and the screw member 160 is inserted. When the screw member 160 is inserted in the recessed region for mounting 121 of the conductive base plate 200 and is screwed in the heat sink 111, the end face side of the head 161 of the screw member 160 is engaged to the protruding engagement unit 131a of the frame member 13. When the screw member 160 is fastened to the heat sink 111, the screw member 160 presses the protruding engagement unit 131a of the frame member 13 in the conductive base plate 200 direction, presses the whole surface of the mounting face of the conductive base plate 200 in equivalent, performs the pressure fixation to the heat sink 111, and connects mutual thermally.

### Sixth Embodiment

As shown in FIG. 19 to FIG. 21, in a package 110b according to a sixth embodiment, the frame member 13 is integrally formed on the conductive base plate 200, the semiconductor device 24 is housed and disposed in the frame member 13, and the external connection terminal 141 of a pair is provided in an extended condition by the sidewall which opposes, respectively. A lid 220 is disposed on the aperture side of the frame member 13 and the aperture is sealed.

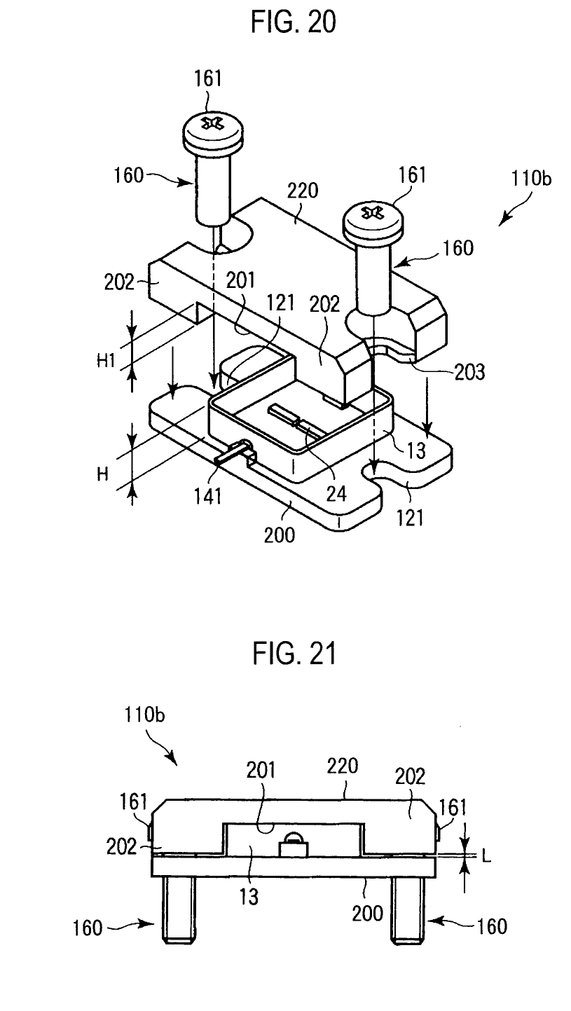

In the lid 220, a pressing unit 201 is provided corresponding to the aperture of the frame member 13, and the pressing unit 201 is disposed by bonding to the aperture side of the frame member 13. In the opposing both ends to which the external connection terminal 141 of the semiconductor device 24 of the pressing unit 201 is not disposed, a leg 202 is formed in H1 size respectively shorter than height size H of the frame member 13 (refer to FIG. 20), and the recessed region 203 for mounting is provided in the intermediate part of the leg 202 corresponding to the recessed region for mounting 121 of the conductive base plate 200, respectively.

Accordingly, when the pressing unit 201 is disposed on the frame member 13 on the conductive base plate 200, the lid 220 is bonded to the plane of the conductive base plate 200 in the state where the leg 202 has the desired gap L (refer to FIG. 21).

According to the above-mentioned configuration, when performing the pressure fixation of the package 110b according to the sixth embodiment to the heat sink 111, the conductive base plate 200 is mounted in the predetermined position on the heat sink 111, the screw member 160 is inserted in the recessed region 203 of the lid 220 and is inserted in the recessed region for mounting 121 of the conductive base plate 200, and is attached tightly by screwing in the screw hole 111a of the heat sink 111.

As for the package 110b according to the sixth embodiment, since the leg 202 of the lid 220 has the gap L between the conductive base plate 200 and the leg 202 of the lid 220 by the screw member 160, the pressing unit 201 of the lid 220 presses the opposing both ends of the frame member 13 in the conductive base plate 200 direction.

In the package 110b according to the sixth embodiment, the pressure fixation of the whole mounting face including the region of the frame member 13 of the conductive base plate 200 is performed to the heat sink 111 in the state where it is pressed in equivalent in the conductive base plate 200 direction, and the heat couplings of the whole mounting face is performed with the heat sink 111.

### Seventh Embodiment

As shown in FIG. 22 to FIG. 24, in a package 110c according to a seventh embodiment, the frame member 13 is provided on the conductive base plate 200. The semiconductor device 24 is housed and disposed in the frame member 13, and the external connection terminal 141 is provided in an extended condition in the both ends which oppose, respectively. The aperture is sealed by which the lid 15a disposed on the aperture side of the frame member 13, and the platy fixture 210 is mounted on the lid 15a.

The opposing both ends where the external connection terminal 141 of the frame member 13 does not exist are formed longer than the linear dimension of the lid 15a, for example, are formed in the approximately the same size as the conductive base plate 200, in the fixture 210. The insertion hole 211 for mounting is provided in the both ends of the fixture 210 corresponding to the opposing both ends of the frame member 13 and the recessed region for mounting 121 of the conductive base plate 200, respectively.

The screw member 160 is inserted in the insertion hole 211 of the fixture 210. After the screw member 160 is disposed along the lines of the outer wall of the frame member 13 and the lid 15a, and is inserted in the recessed region for mounting 121 of the conductive base plate 200, the screw member 160 is screwed in the screw hole 111a of the heat sink 111.

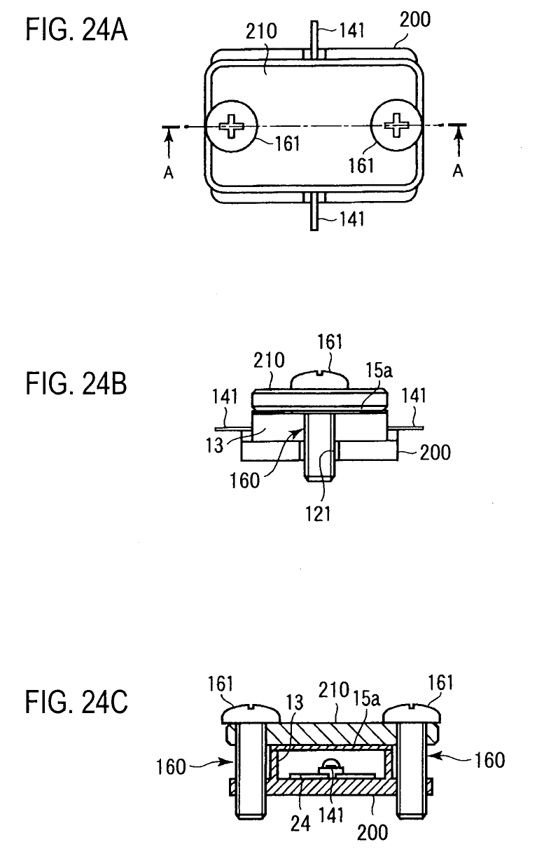

The end face side of the head 161 is engaged to the perimeter of the insertion hole 211 of the fixture 210, and the screw member 160 gives clamping power to the opposing both ends of the frame member 13 with the lid 15a, and presses the conductive base plate 200 on the heat sink 111 (refer to FIGS. 24B and 24C).

According to the above-mentioned configuration, when performing the pressure fixation of the package 110c according to the seventh embodiment to the heat sink 111, the conductive base plate 200 is mounted on the predetermined position on the heat sink 111, and the fixture 210 is mounted on the lid 15a.

The screw member 160 is inserted in the insertion hole 211 of the fixture 210, and the screw member 160 is inserted in the recessed region for mounting 121 of the conductive base plate 200, and the screw member 160 is attached tightly by being screwed in the screw hole 111a of the heat sink 111.

The package 110c according to the seventh embodiment adds the suppress strength of conductive base plate 200 direction for the perimeter of the insertion hole 211 of the fixture 210 at the end face side of the head 161 of the screw member 160, and presses the opposing both ends of the frame member 13 with the lid 15c in the same direction.

In the package 110c according to the seventh embodiment, the pressure fixation of the whole mounting face including the region of the frame member 13 of the conductive base plate 200 is performed to the heat sink 111 in the state where it is pressed in equivalent in the conductive base plate 200 direction, and the heat couplings of the whole mounting face is performed with the heat sink 111.

### Eighth Embodiment

As shown in FIG. 25, a package 110f according to an eighth embodiment is composed by forming a stepped unit 131f in the inner circumference of the aperture of the frame member 13 in the seventh embodiment, and performing the inner package so that a lid 15f may be dropped into the stepped unit 131f.

As for the package 110f according to the eighth embodiment, the fixture 210 is disposed on the aperture side of the stepped unit 131f of the frame member 13 in the state where it mounted on the predetermined position of the heat sink 111. The fixture 210 is screwed on a screw hole 111a of the heat sink 111, after the screw member 160 is inserted in the insertion hole 211 and the screw member 160 is inserted in the recessed region for mounting 121 of the conductive base plate 200.

The end face side of the head 161 is engaged to the perimeter of the insertion hole 211 of the fixture 210, and the screw member 160 gives clamping power to the aperture side edge part of the stepped unit 131f of the frame member 13 via the fixture 210, and presses the conductive base plate 200 on the heat sink 111.

In the package 110f according to the eighth embodiment, the pressure fixation of the whole mounting face including the region of the frame member 13 of the conductive base plate 200 is performed in the state where it is pressed in equivalent in the conductive base plate 200 direction to the heat sink 111, and the heat couplings of the whole mounting face is performed with the heat sink 111.

### Other Embodiments

While the present invention is described in accordance with the aforementioned first embodiment and modified examples 1 through 4 of the first embodiment, and second through eighth embodiments, it should not be understood that the description and drawings that configure part of this disclosure are to limit the present invention. This disclosure makes clear a variety of alternative embodiments, working examples, and operational techniques for those skilled in the art.

The present invention can perform various modifications in the range which does not depart from the gist in an implementation phase, without limiting to the above-mentioned embodiments. Furthermore, an invention of various stages is included in the above-mentioned embodiments, and various inventions may be extracted by the proper combination in a plurality of constituent features disclosed.

For example, even if some constituent features are deleted from all the constituent features shown in the embodiments, when the problem described in the column of the “Technical Problem” is solvable, and the effect described in the “Advantageous Effects of Invention” is obtained, the configuration from which the constituent features are deleted may be extracted as an invention.

In the modified example 1 of the first embodiment, although disclosed about the case where it has the hollow area of the cross shape where the frame shape of the ceramic wall 16 continued, it is not limited to these and may have the shape of arbitrary hollow areas according to the predetermined circuit configuration and disposition shape of the circuit board.

In the modified example 2 of the first embodiment, although disclosed about the case of the ceramic wall 16 having the frame shape of the octagon, it is not limited to these and may have the frame shape of arbitrary polygons.

In addition, it cannot be overemphasized that the high frequency semiconductor devices, to which the package according to the embodiments of the present invention is applied, are applicable not only to FETs (Field Effect Transistors) but also other amplifying elements, such as LDMOS (Laterally Diffused Metal-Oxide-Semiconductor) FETS, HEMTs (High Electron Mobility Transistors), HBTs (Hetero-junction Bipolar Transistors), and MEMS (Micro Electro Mechanical Systems) devices.

Such being the case, the present invention covers a variety of embodiments, whether described or not.

### INDUSTRIAL APPLICABILITY

A package according to the present invention has a wide range of application fields, such as an internally matched power amplifier, a power MMIC (Monolithic Microwave Integrated Circuit), a microwave power amplifier, a millimeter wave power amplifier, and a high frequency MEMS device.

### REFERENCE SIGNS LIST

10: Ceramic cap;
11a, 11b, 12, 14, 15a, 15b: Bonding wire;
13: Frame member;
14a: Metal seal ring;
15, 15a, 15d, 15e, 15f, 220: Lid;
16: Ceramic wall;
17a, 17b: Input matching circuit;
18a, 18b: Output matching circuit;
19a: Input stripline;
19b: Output stripline;
20: Insulating layer;
21a, 21b: Terminal electrode;
24: Semiconductor device;
25a, 25b, 25c, 25d, 111a: Screw hole;
26a, 26b: Input circuit substrate;
28a, 28b: Output circuit substrate;
100: Substrate;
110, 110a, 110b, 110c, 110d, 110e, 110f: Package;
111: Heat sink;
121: Recessed region for mounting;
122: Drain electrode;
124: Gate electrode;
126: Source electrode;
131: Engagement unit;
131a: Protruding engagement unit;
131f: Stepped unit:
141: External connection terminal;
151, 151a: Pressing unit:
151d, 152a: Recessed region;
152: Insertion hole;
160: Screw member;
161: Head;
200: Conductive base plate;
201: Pressing unit;
202: Leg;
203: Recessed region for mounting;
210: Fixture;
211: Insertion hole for mounting;
P1: Input terminal;
P2: Output terminal;
G1, G2, . . . , G4: Gate terminal electrode;
S1, S2, . . . , S5: Source terminal electrode;
D: Drain terminal electrode; and
SC1 to SC5: VIA hole.

1. A package comprising:
a conductive base plate;
a ceramic wall configured to house a semiconductor device and a circuit board disposed adjoining of the semiconductor device, the ceramic wall configured to be disposed on the conductive base plate, the ceramic wall configured to have a frame shape having a screw hole in each of four corners;
a metal seal ring configured to have a framed shape and be disposed on the ceramic wall; and
a ceramic cap configured to be disposed on the metal seal ring, and wherein
the ceramic wall is screwed to the conductive base plate through the screw hole.

2. The package according to claim 1, wherein
the ceramic wall has a cross-shaped hollow area by forming a corner part of the frame shape thickly.

3. The package according to claim 1, wherein
the ceramic wall has a polygonal shape with hollow area by forming a corner part of the frame shape thickly, and forming a side part of the frame shape in linear shape.

4. The package according to claim 1, wherein
the ceramic wall has a hollow area by forming a corner part of the frame shape in the curve profile thickly, and forming a side part of the frame shape in linear shape.

5. A package comprising:
a frame member of a frame shape configured to be provided on a mounting base, a semiconductor device being housed and disposed in the frame member;
a lid disposed on an aperture side of the frame member; and
fixing means configured to press both ends opposing at least one of the lid and the frame member in a direction of the mounting base, and to perform pressure fixation of the mounting base to a radiator.

6. The package according to claim 5, wherein
the lid includes a pressing unit, and the fixing means presses the pressing unit in the direction of the mounting base, and performs pressure fixation of the mounting base to the radiator.

7. The package according to claim 6, wherein
a head of a screw member presses the frame member in the mounting base direction via the pressing unit, and the pressing unit performs pressure fixation of the mounting base to the radiator, by inserting the screw member in the pressing unit, inserting the screw member in the mounting base, and screwing the screw member in the radiator.

8. The package according to claim 6, wherein
the frame member includes a rigid body part pressed in the mounting base direction via the lid while intervening between the pressing unit of the lid and the mounting base.

9. The package according to claim 8, wherein
the rigid body part is pressed in the mounting base direction with the pressing unit by the head of the screw member, and the rigid body part performs pressure fixation of the mounting base to the radiator, by screwing the rigid body part in the radiator after the screw member inserted in the pressing unit is inserted in the rigid body part and the screw member is inserted in the mounting base.

10. The package according to claim 5, wherein
the fixing means is a platy fixture configured to be mounted on the lid, to press the both ends opposing at least one of the lid and the frame member in the mounting base direction, and to perform pressure fixation of the mounting base to the radiator.

11. The package according to claim 10, wherein
the head of the screw member presses the lid and the frame member in the mounting base direction via the fixture, and the fixture performs pressure fixation of the mounting base to the radiator, by screwing the fixture in the radiator after the screw member is inserted in both ends of the fixture and the screw member is inserted in the mounting base.

12. A fabrication method for a package comprising:
forming a conductive base plate;
forming a ceramic wall having a frame shape including a screw hole in four corners on the conductive base plate, the ceramic wall housing a semiconductor device and an input circuit substrate and an output circuit substrate by adjoining of the semiconductor device;
forming a metal seal ring on the ceramic wall;
forming a ceramic cap on the metal seal ring; and
screwing the ceramic wall to the conductive base plate through the screw hole.

13. The fabrication method for a package according to claim 11 further comprising:
forming an insulating layer on the conductive base plate in an input/output unit of the ceramic wall;
forming an input stripline and an output stripline on the insulating layer;
forming an input matching circuit connected to the input stripline on the input circuit substrate;
forming an output matching circuit connected to the output stripline on the output circuit substrate; and
connecting the semiconductor device, the input matching circuit, and the output matching circuit using a bonding wire.

14. The fabrication method for a package according to claim 11, wherein
the ceramic wall has a cross-shaped hollow area by forming a corner part of the frame shape thickly.

15. The fabrication method for a package according to claim 11, wherein
the ceramic wall has a polygonal shape hollow area by forming a corner part of the frame shape thickly.

16. The fabrication method for a package according to claim 11, wherein
the ceramic wall has a hollow area by forming a corner part of the frame shape in the curve profile thickly, and forming a side part of the frame shape in linear shape.
